(19) United States
(12) Patent Application Publication
(10) Pub. No.: US 2014/0015040 A1
(43) Pub. Date: Jan. 16, 2014

(54) POWER SEMICONDUCTOR DEVICE AND FABRICATION METHOD THEREOF

(71) Applicants: Yung-Fa Lin, Hsinchu City (TW); Chia-Hao Chang, Hsinchu City (TW); Yi-Chun Shih, Nantou County (TW)

(72) Inventors: Yung-Fa Lin, Hsinchu City (TW); Chia-Hao Chang, Hsinchu City (TW); Yi-Chun Shih, Nantou County (TW)

(73) Assignee: ANPEC ELECTRONICS CORPORATION, Hsin-Chu (TW)

(21) Appl. No.: 13/589,199

(22) Filed: Aug. 20, 2012

(30) Foreign Application Priority Data
Jul. 11, 2012 (TW) 101124976

(51) Int. Cl. H01L 29/78

(52) U.S. Cl. 257/330; 257/E29.262

(57) ABSTRACT

A power semiconductor device includes a substrate, a semiconductor layer grown on the substrate, a plurality of alternately arranged first conductivity type doping trenches and second conductivity type doping trenches in the semiconductor substrate, a first diffusion region of the first conductivity type around each of the first conductivity type doping trenches, and a second diffusion region of the second conductivity type around each of the second conductivity type doping trenches, wherein distance between an edge of the first conductivity type doping trench and PN junction between the first and second diffusion regions substantially equals to a distance between an edge of the second conductivity type doping trench and the PN junction.

### BACKGROUND OF THE INVENTION

1. Field of the Invention

The present invention relates generally to a power semiconductor device. More particularly, the present invention relates to a superjunction power semiconductor device and fabrication method thereof.

2. Description of the Prior Art

As known in the art, power semiconductor devices are mainly used in power management; for instance, in switching power supplies, in management integrated circuits in the core or peripheral regions of computers, in backlight power supplies, and in electric motor controls. This type of power semiconductor devices, as described above, includes an insulated gate bipolar transistor (IGBT), a metal-oxide-semiconductor field effect transistor (MOSFET), or a bipolar junction transistor (BJT), among which the MOSFET is the most widely utilized because of its energy saving properties and its ability to provide faster switch speed.

To sustain high voltages, the prior art MOSFET power devices typically increase the thickness of the drift layer or reduce the doping concentration to enhance the breakdown voltage of power devices. However, the drift layer is also the current path when the transistor is turned on. Reduction of the drift layer doping concentration or increase in the thickness can enhance the element withstand voltage characteristics, but on the other hand, it also led to the on-resistance (Rds, on) rise. To cope with such problem, the superjunction structure has been developed.

However, the prior art superjunction power semiconductor devices still have several drawbacks. For example, the asymmetric doping concentration distribution between the N type and P type regions leads to charge imbalance. It is desirable to provide an improved superjunction power semiconductor device having symmetric doping concentration distribution between the N type and P type regions to solve the issue of charge imbalance, and to further reduce the on-resistance.

### SUMMARY OF THE INVENTION

It is one objective to provide an improved superjunction power semiconductor device to solve the above-mentioned prior art problems and shortcomings.

According to the claimed invention, a power semiconductor device includes a substrate with a first conductivity type; a semiconductor layer grown on the substrate, the semiconductor layer having a the first conductivity type; a plurality of alternately arranged first conductivity type doping trenches and second conductivity type doping trenches in the semiconductor substrate; a first diffusion region of the first conductivity type, in the semiconductor layer and around each of the first conductivity type doping trenches; and a second diffusion region of the second conductivity type, in the semiconductor layer and around each of the second conductivity type doping trenches, wherein a distance between an edge of the first conductivity type doping trench and a PN junction between the first and second diffusion regions substantially equals to a distance between an edge of the second conductivity type doping trench and the PN junction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIGS. 1-13 are schematic, cross-sectional diagrams illustrating a method for fabricating a superjunction power semiconductor device in accordance with one embodiment of this invention; and

FIGS. 14-18 are schematic, cross-sectional diagrams illustrating a method for fabricating a superjunction power semiconductor device in accordance with another embodiment of this invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that other embodiments may be utilized and that structural, logical and electrical changes may be made without departing from the spirit and scope of the present invention. The following detailed description is, therefore, not to be taken in a limiting sense, and the scope of the present invention is defined by the appended claims.

The present invention pertains to a double-doping trench-type superjunction power semiconductor device and fabrication method thereof. In one exemplary embodiment, the superjunction power semiconductor device is fabricated by employing respective N type and P type ion implantation processes, followed by etching processes to form the columns of doping regions. Of course, the present invention is not limited to such implementation and embodiment. Other methods, such as tilt-angle ion implantation, multiple vertical ion implantation and etching, or diffusing and doping methods may be used. One or more implementations of the present invention will now be described with reference to the attached drawings, wherein like reference numerals are used to refer to like elements throughout, and wherein the illustrated structures are not necessarily drawn to scale. The exemplary embodiment and drawings describe a trench-type MOS structure, however, it is to be understood that the present invention may be applicable to the fabrication other types of power semiconductor devices such as planar-type MOS structures.

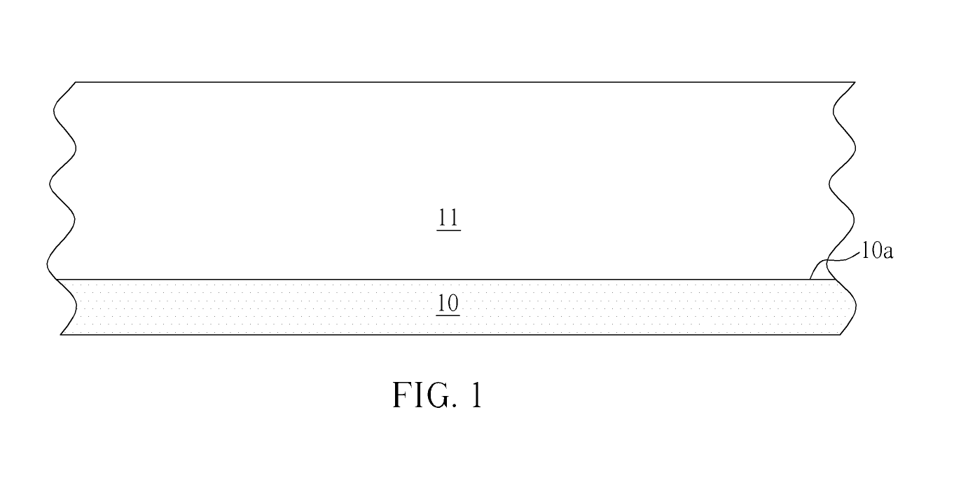

FIGS. 1-13 are schematic, cross-sectional diagrams illustrating a method for fabricating a superjunction power semiconductor device in accordance with one embodiment of this invention. As shown in FIG. 1, a substrate or a semiconductor substrate 10 such as an N+ silicon substrate is provided. A semiconductor layer 11 such as a P type epitaxial silicon layer or an N type epitaxial silicon layer is grown on a main surface 10a of the semiconductor substrate 10. According to the embodiment, the semiconductor layer 11 is an N type epitaxial silicon layer having a thickness t of about 5-100 micrometers, for example, 45 micrometers, but not limited thereto. According to the embodiment, the semiconductor layer 11 is preferably a lightly doped epitaxial layer having a doping concentration of less than 1E14 atoms/cm3, for example.

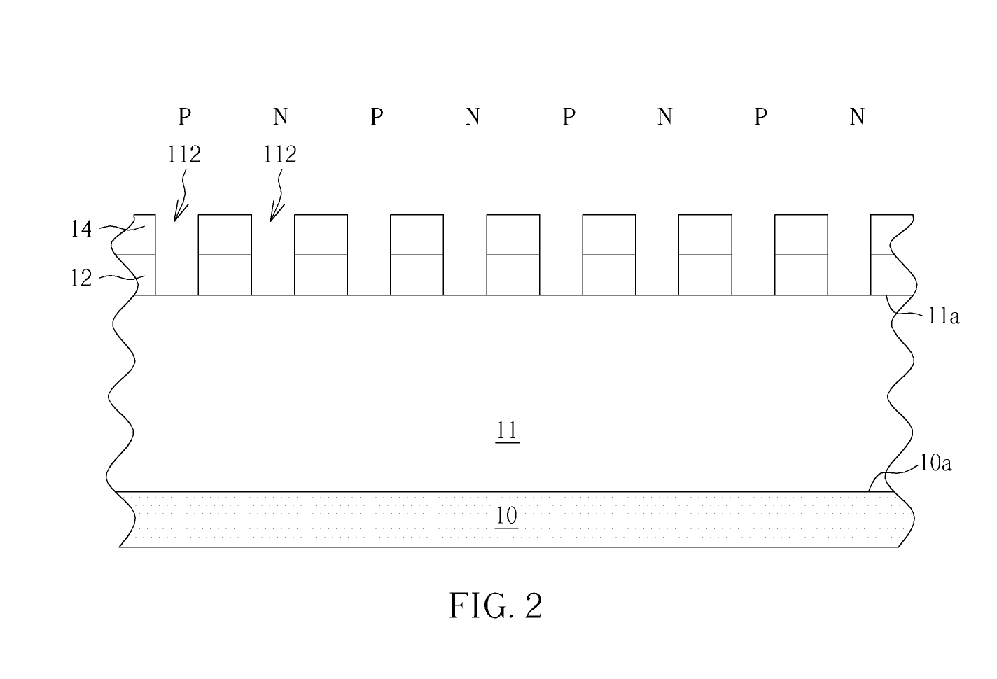

As shown in FIG. 2, a hard mask pattern 12 is formed on the surface of the semiconductor layer 11. The hard mask pattern 12 includes openings 112 that expose a portion of the surface 11a of the semiconductor layer 11. The openings define the position of the deep trenches to be etched into the semiconductor layer 11 in a later stage. According to the embodiment, the hard mask pattern 12 may be composed of silicon oxide, but not limited thereto. The hard mask pattern may be formed by using a patterned photoresist layer 14 and conventional lithographic and etching processes, which are known in the art and therefore the details are not described herein. At this point, the openings 112 in the hard mask pattern 12 may comprise alternately arranged P type doping openings and N type doping openings as specifically indicated above each of the openings 112.

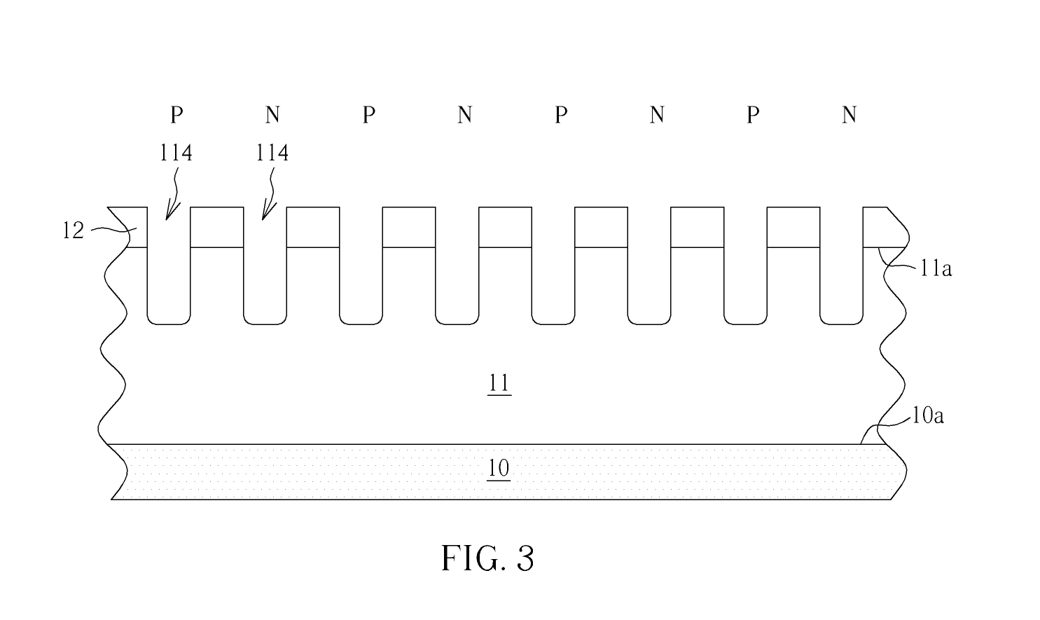

As shown in FIG. 3, subsequently, an anisotropic dry etching process is carried out to etch the semiconductor layer 11 through the openings 112, thereby forming a plurality of first trenches 114. Likewise, the first trenches 114 may comprise alternately arranged P type doping trenches and N type doping trenches as specifically indicated above each of the trenches 114.

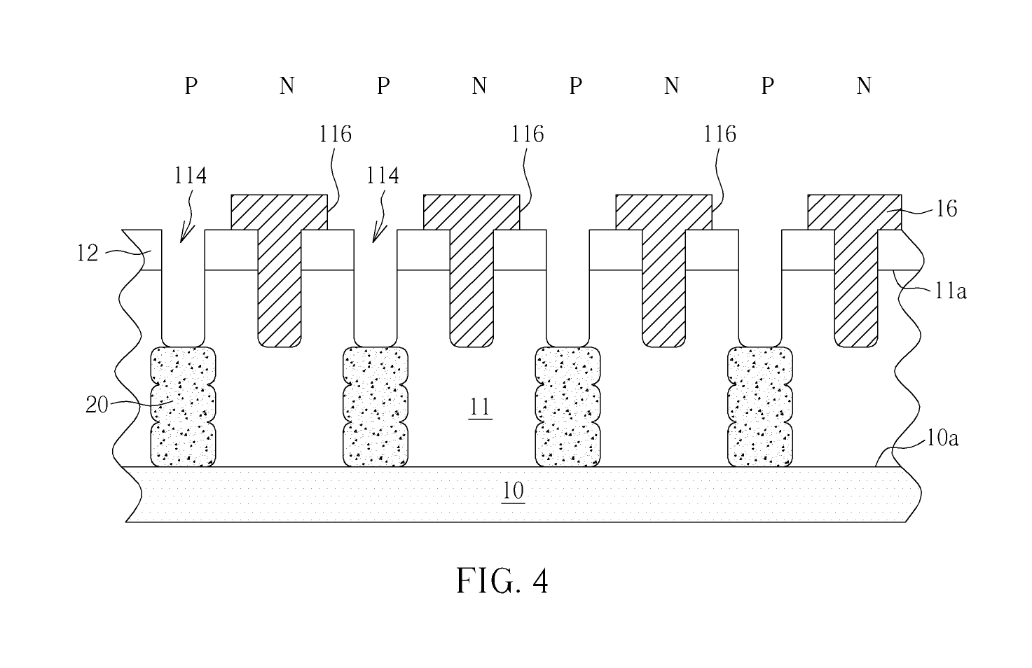

As shown in FIG. 4, a photoresist layer 16 is formed on the semiconductor layer 11. The photoresist layer 16 fills into the first trenches 114 and covers the hard mask pattern 12. A lithographic process is then performed to form openings 116 in the photoresist layer 16 such that the openings 116 only reveal the plurality of P type doping trenches of the first trenches 114. At this point, the patterned photoresist layer 16 still covers the N type doping trenches of the first trenches 114. Thereafter, multiple ion implantation steps, for example, with different implant energies, are carried out to form P type doping regions 20 in the semiconductor layer 11 through the revealed P type doping trenches of the first trenches 114. Subsequently, the patterned photoresist layer 16 is stripped.

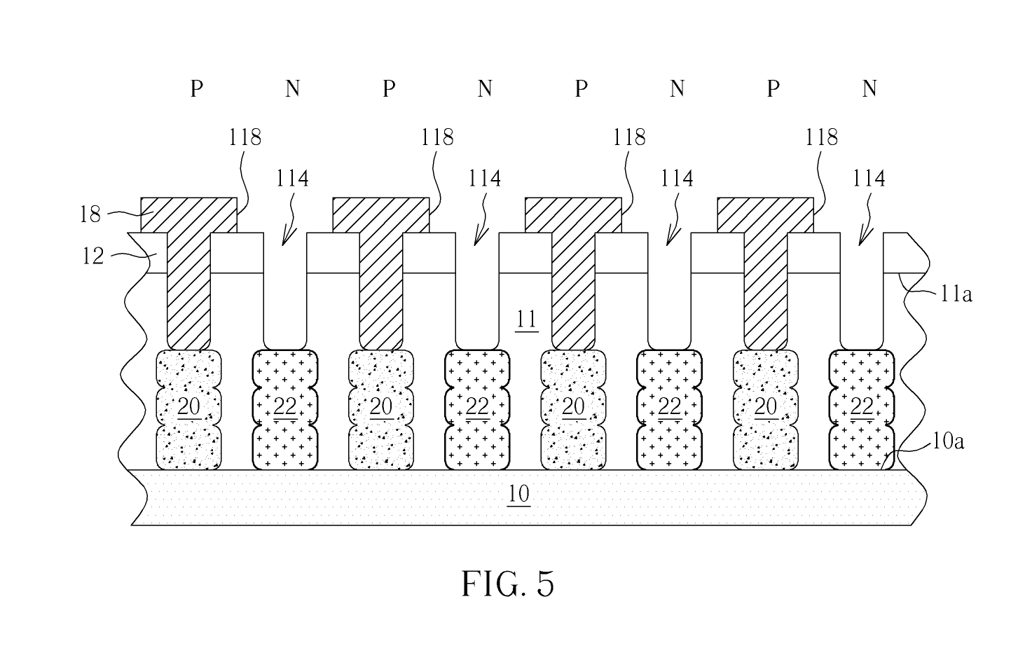

As shown in FIG. 5, after the removal of the patterned photoresist layer 16, a photoresist layer 18 is coated onto the semiconductor layer 11. The photoresist layer 18 also fills into the first trenches 114 and covers the hard mask pattern 12. Likewise, a lithographic process is then performed to form openings 118 in the photoresist layer 18 such that the openings 118 only reveal the plurality of N type doping trenches of the first trenches 114. At this point, the patterned photoresist layer 18 still covers the P type doping trenches of the first trenches 114. Thereafter, multiple ion implantation steps, for example, with different implant energies, are carried out to form N type doping regions 22 in the semiconductor layer 11 through the revealed N type doping trenches of the first trenches 114. Subsequently, the patterned photoresist layer 18 is stripped. Of course, the steps in FIG. 4 and FIG. 5 are interchangeable.

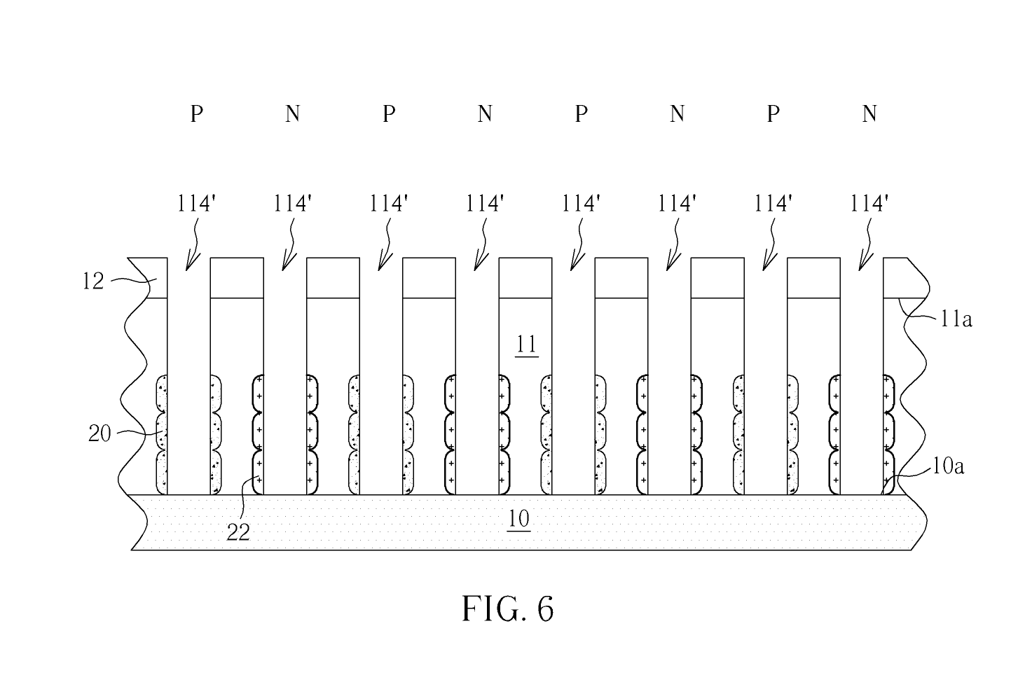

As shown in FIG. 6, after forming the P type doping regions 20 and N type doping regions 22, a second anisotropic dry etching process is performed using the hard mask pattern 12 as an etching mask to continue to etch the semiconductor layer 11 through the plurality of first trenches 114, thereby forming a plurality of second trenches 114′ having a trench depth that substantially reaches the semiconductor substrate 10. According to the embodiment, the second trenches 114′ penetrate through the P type doping regions and the N type doping regions respectively. However, it is to be understood that the second trenches 114′ may not penetrate through the P type doping regions and the N type doping regions in other embodiments.

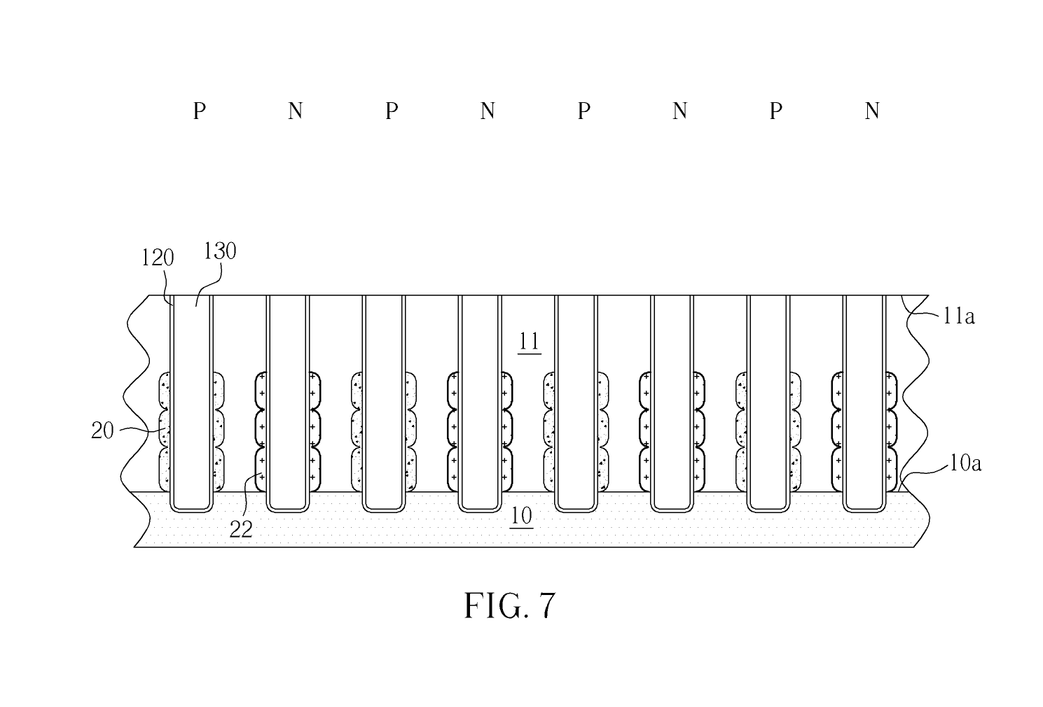

As shown in FIG. 7, after the formation of the second trenches 114′, a liner layer 120, for example, silicon oxide layer, is formed on the bottom surface and sidewall surface of the second trenches 114′. According to the embodiment, the liner layer 120 may be a dielectric layer and may be formed by using thermal oxidation methods, but not limited thereto. Subsequently, a chemical vapor deposition (CVD) process is performed to deposit a trench fill dielectric 130 in a blanket manner. The trench fill dielectric 130 may be a silicon oxide layer and fills the second trenches 114′. The trench fill dielectric 130 also covers the hard mask pattern 12. A chemical mechanical polishing (CMP) process is then performed to remove a portion of the trench fill dielectric 130. Thereafter, the hard mask pattern 12 is removed.

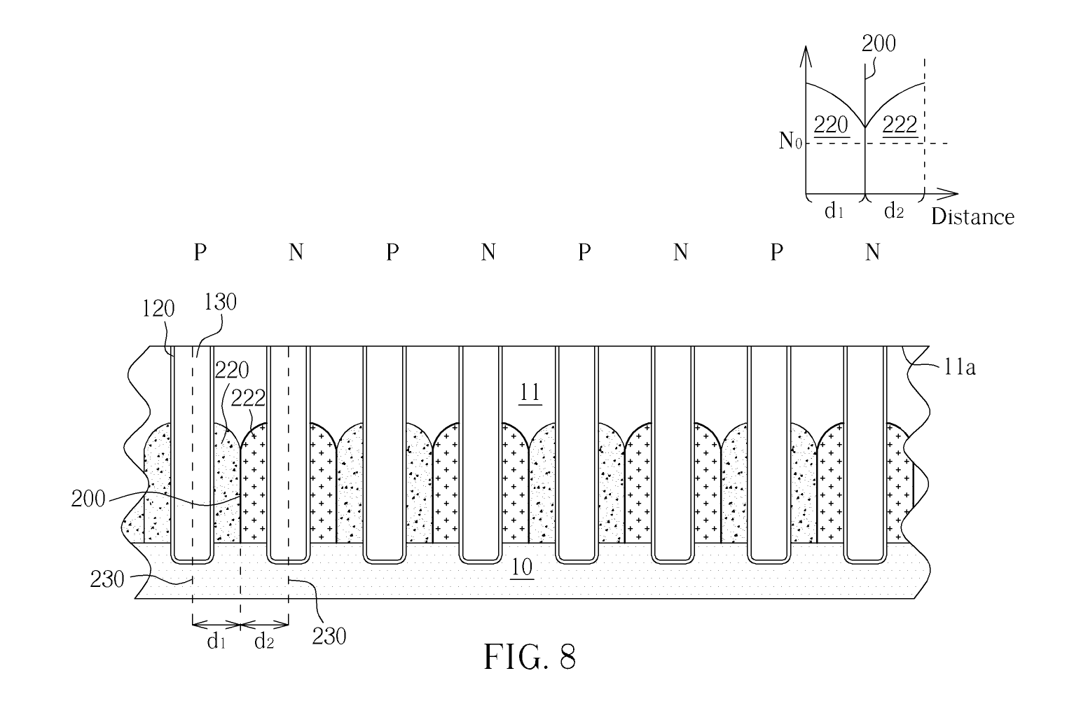

As shown in FIG. 8, a thermal drive-in process is performed to diffuse dopants inside the P type doping regions 20 and the N type doping regions 22, thereby forming P type diffusion regions 220 and N type diffusion regions 222. A PN junction 200 is formed between the P type diffusion regions 220 and N type diffusion regions 222. According to the embodiment, the distances between the PN junction 200 and centerline 230 of the adjacent second trenches 114′ are d1 and d2 as specifically indicated in the figure, wherein d1 is substantially equal to d2, but d1 is not limited to be equal to d2. The doping concentration distribution diagram (concentration vs. distance) corresponding to the PN junction 200 is shown in the upper right portion of FIG. 8, which represents a symmetric concentration gradient (N0 is the doping concentration of the semiconductor layer 11).

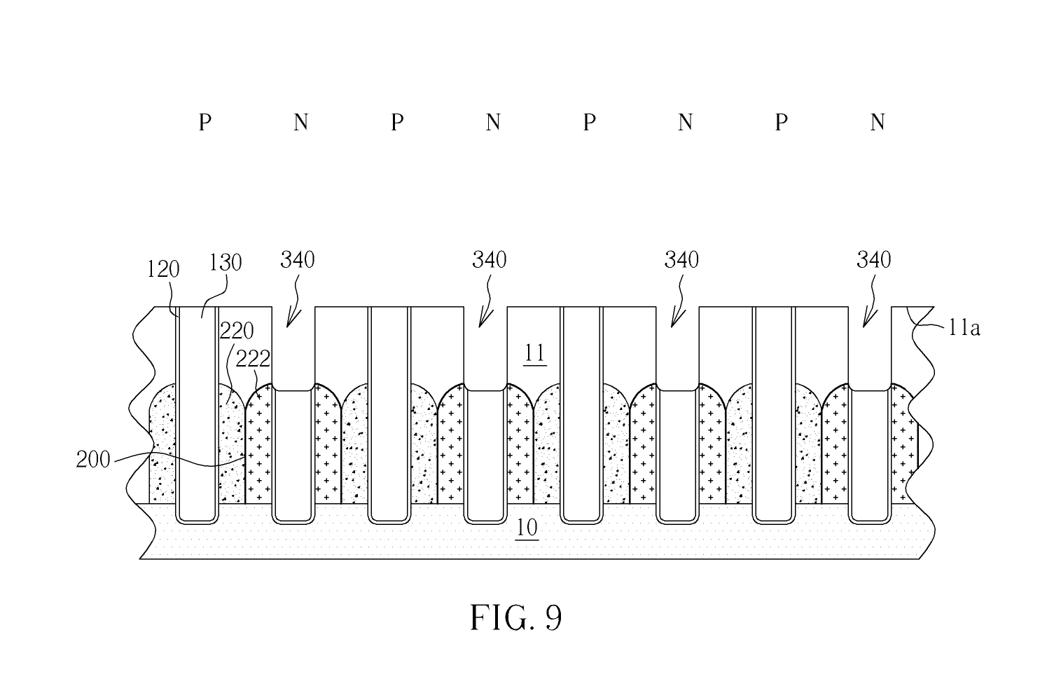

As shown in FIG. 9, a photoresist layer (not shown) is formed to cover the semiconductor layer 11. A lithographic process is then performed to form openings (not shown) to only reveal the N type doping trenches of the plurality of second trenches 114′. Subsequently, an etching process such as a dry etching process is performed to remove a portion of the revealed trench fill dielectric 130 from the N type doping trenches of the plurality of second trenches 114′, thereby forming a plurality of recessed gate trenches 340. The photoresist layer is then stripped.

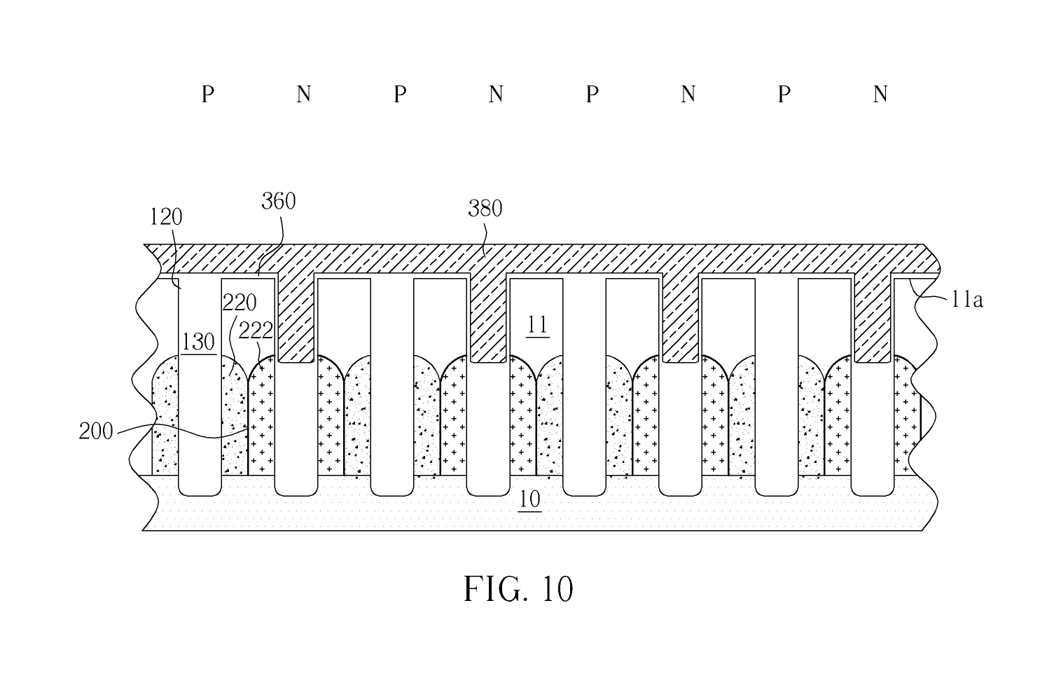

As shown in FIG. 10, a thermal oxidation process is performed to form a gate oxide layer 360 on the revealed surface of the semiconductor layer 11 including the surface 11a of the semiconductor layer 11 and the surface of the recessed gate trenches 340. A CVD process is then performed to deposit a polysilicon layer 380 on the semiconductor layer 11 in a blanket manner.

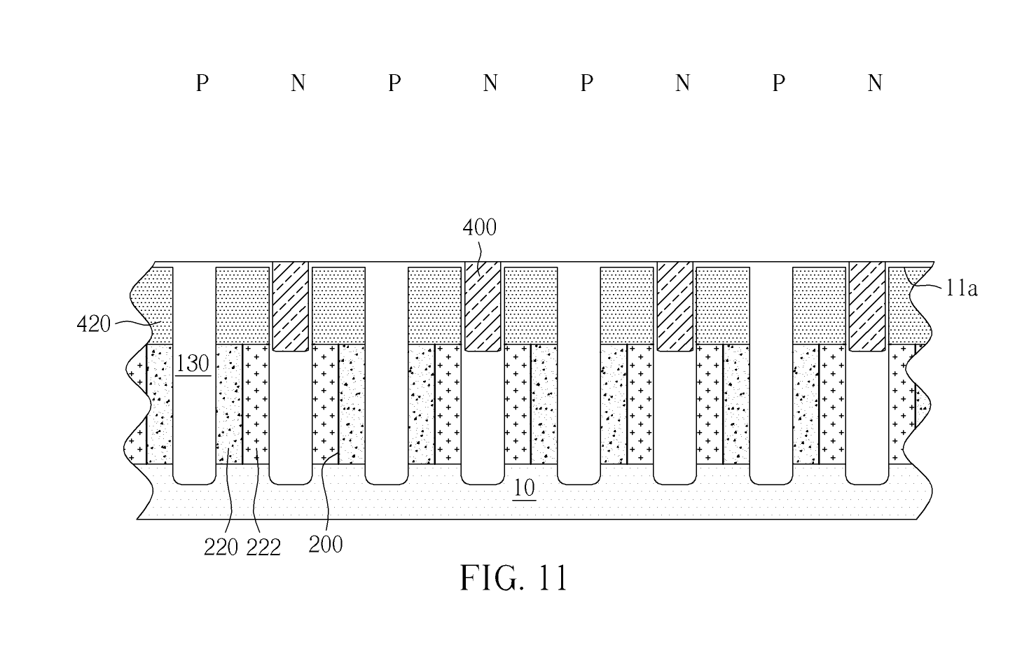

As shown in FIG. 11, subsequently, a polishing process or an etching process may be performed to planarize the polysilicon layer 380 and to reveal the gate oxide layer 360 on the surface 11a of the semiconductor layer 11, thereby forming the trench gates 400 of the power devices in the recessed gate trenches 340 in a self-aligned manner. Subsequently, P well doping or implantation is carried out to form P well 420 in the surface 11a of the semiconductor layer 11.

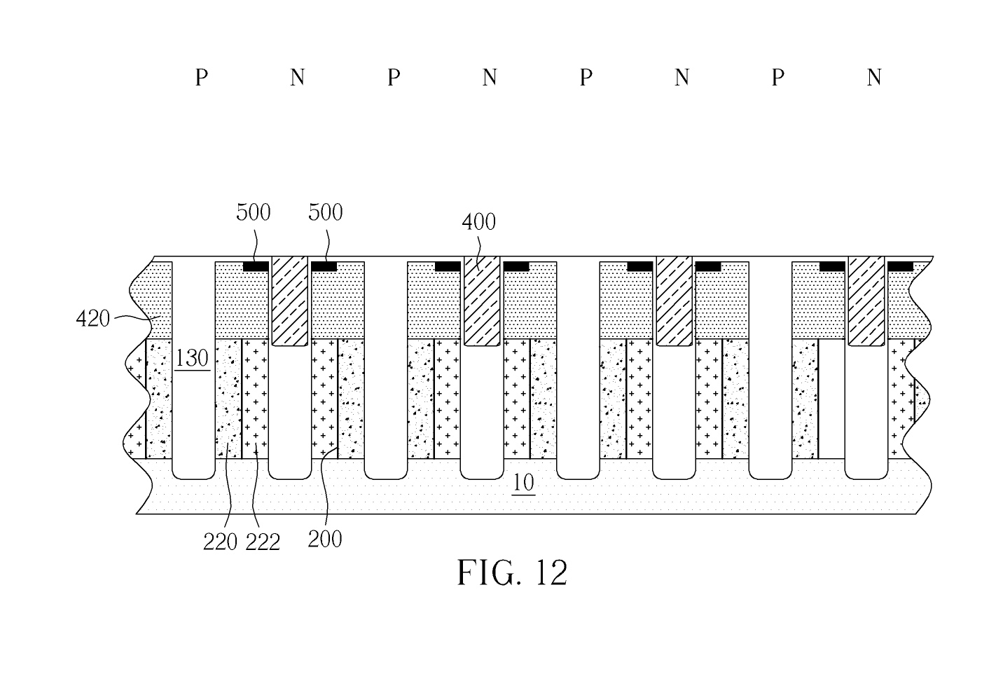

As shown in FIG. 12, after the formation of the P well 420, a photoresist layer is formed to define the source diffusion region. An N+ doping process is then performed to form an N+ source region 500 in the P well 420 next to the trench gate 400. Subsequently, the photoresist layer is removed. A thermal process may be performed to activate the dopants.

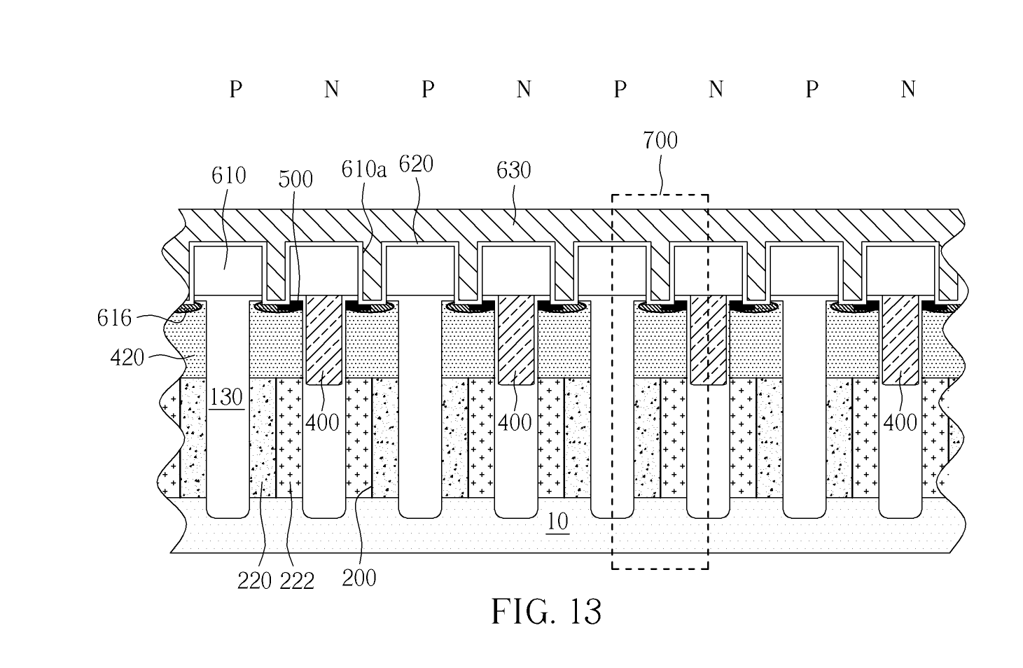

As shown in FIG. 13, a contact element is then fabricated. First, a dielectric layer 610 is deposit in a blanket manner. A lithographic process and an etching process are performed to form contact openings 610a in the dielectric layer 610. The openings 610a reveal a portion of the P well 420 and a portion of the N+ source regions 500. An additional ion implantation process may be carried out to implant dopants 616 with a predetermined concentration into the P well through the openings 610a in order to reduce contact resistance. Subsequently, a barrier layer 620 such as titanium-titanium nitride is deposit in a blanket manner. A contact metal layer 630 is then deposited to fill the contact openings 610a. In FIG. 13, a power device cell unit 700 is indicated by dashed line.

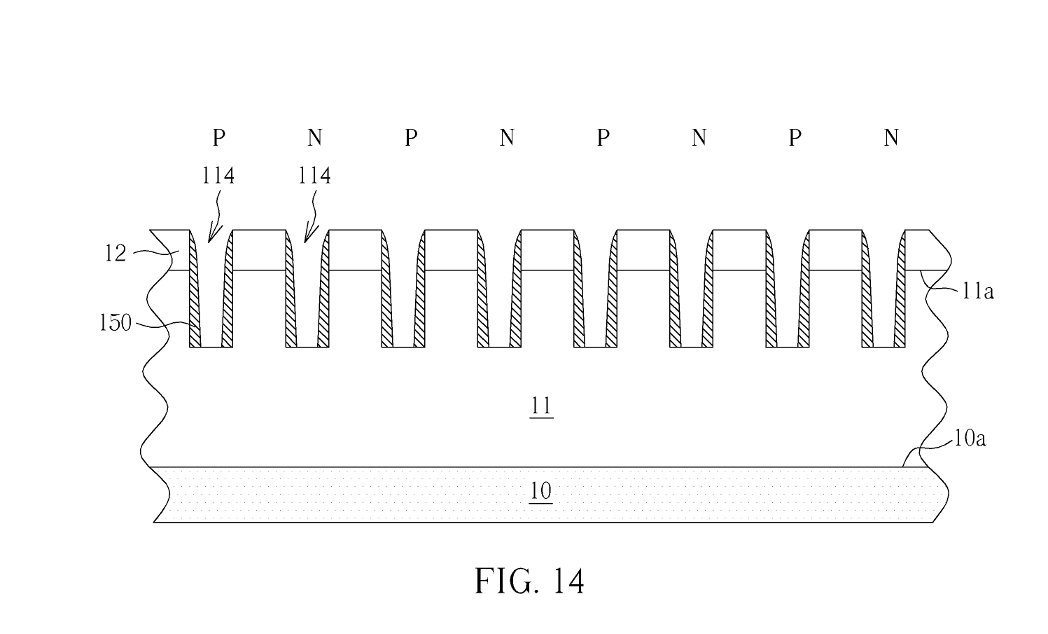

FIGS. 14-18 are schematic, cross-sectional diagrams illustrating a method for fabricating a superjunction power semiconductor device in accordance with another embodiment of this invention, wherein the step of FIG. 14 follows the step of FIG. 3. As shown in FIG. 14, after the formation of the plurality of first trenches 114, a spacer 150 is formed on the sidewall of each of the first trenches 114. According to this embodiment, the spacer 150 may be composed of silicon nitride or silicon oxide.

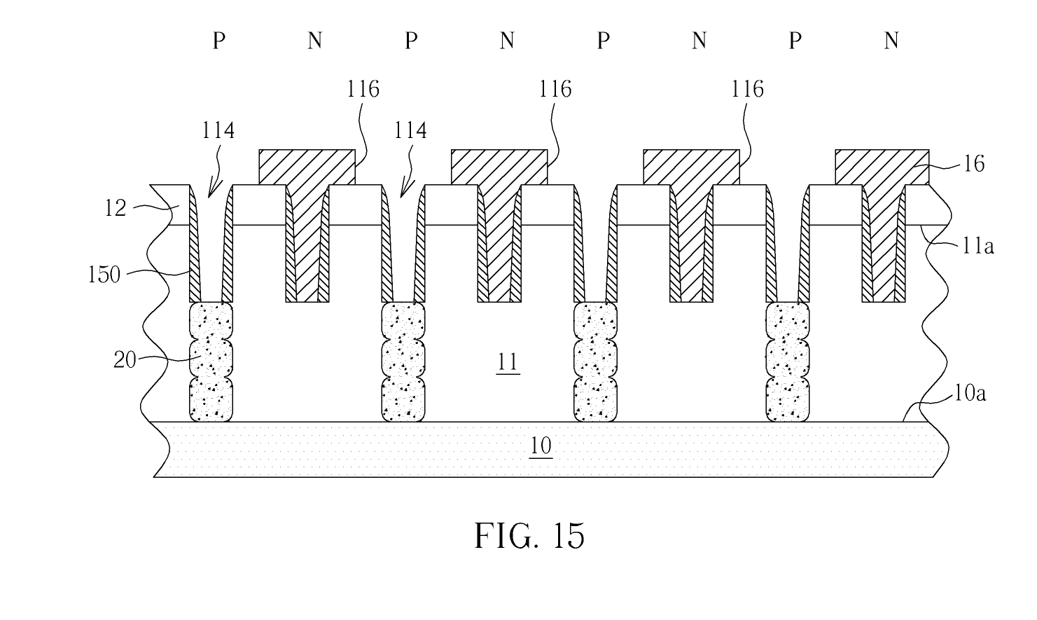

As shown in FIG. 15, similarly to FIG. 4, a photoresist layer 16 is formed on the semiconductor layer 11. The photoresist layer 16 fills into the first trenches 114 and covers the hard mask pattern 12. A lithographic process is then performed to form openings 116 in the photoresist layer 16 such that the openings 116 only reveal the plurality of P type doping trenches of the first trenches 114. At this point, the patterned photoresist layer 16 still covers the N type doping trenches of the first trenches 114. Thereafter, multiple ion implantation steps, for example, with different implant energies, are carried out to form P type doping regions 20 in the semiconductor layer 11 through the revealed P type doping trenches of the first trenches 114. Subsequently, the patterned photoresist layer 16 is stripped.

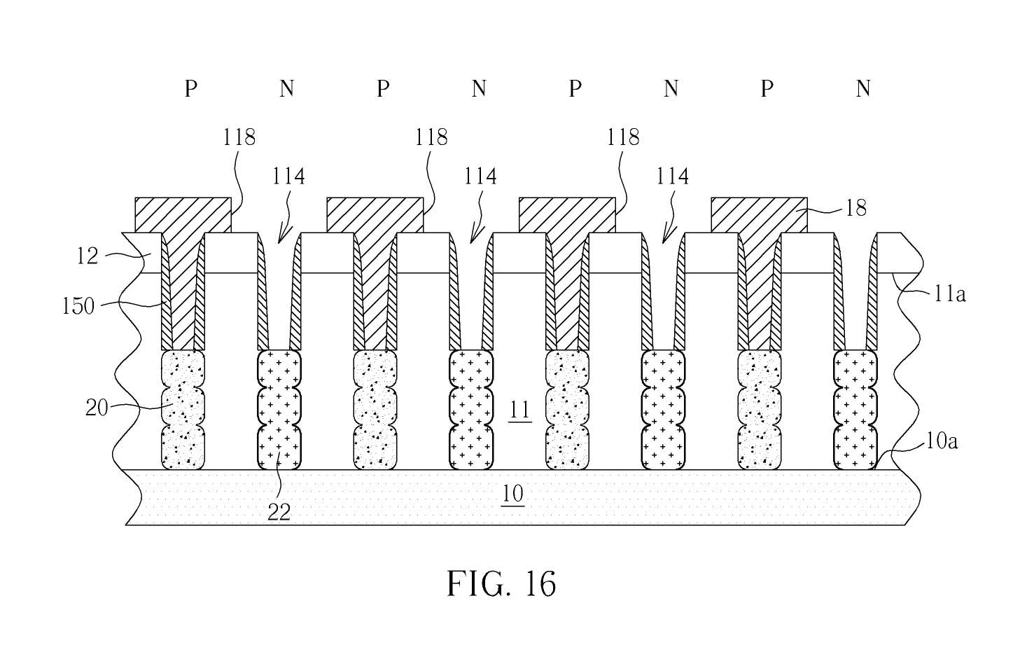

As shown in FIG. 16, similarly to FIG. 5, after the removal of the patterned photoresist layer 16, a photoresist layer 18 is coated onto the semiconductor layer 11. The photoresist layer 18 also fills into the first trenches 114 and covers the hard mask pattern 12. Likewise, a lithographic process is then performed to form openings 118 in the photoresist layer 18 such that the openings 118 only reveal the plurality of N type doping trenches of the first trenches 114. At this point, the patterned photoresist layer 18 still covers the P type doping trenches of the first trenches 114. Thereafter, multiple ion implantation steps, for example, with different implant energies, are carried out to form N type doping regions 22 in the semiconductor layer 11 through the revealed N type doping trenches of the first trenches 114. Subsequently, the patterned photoresist layer 18 is stripped. Of course, the steps in FIG. 15 and FIG. 16 are interchangeable.

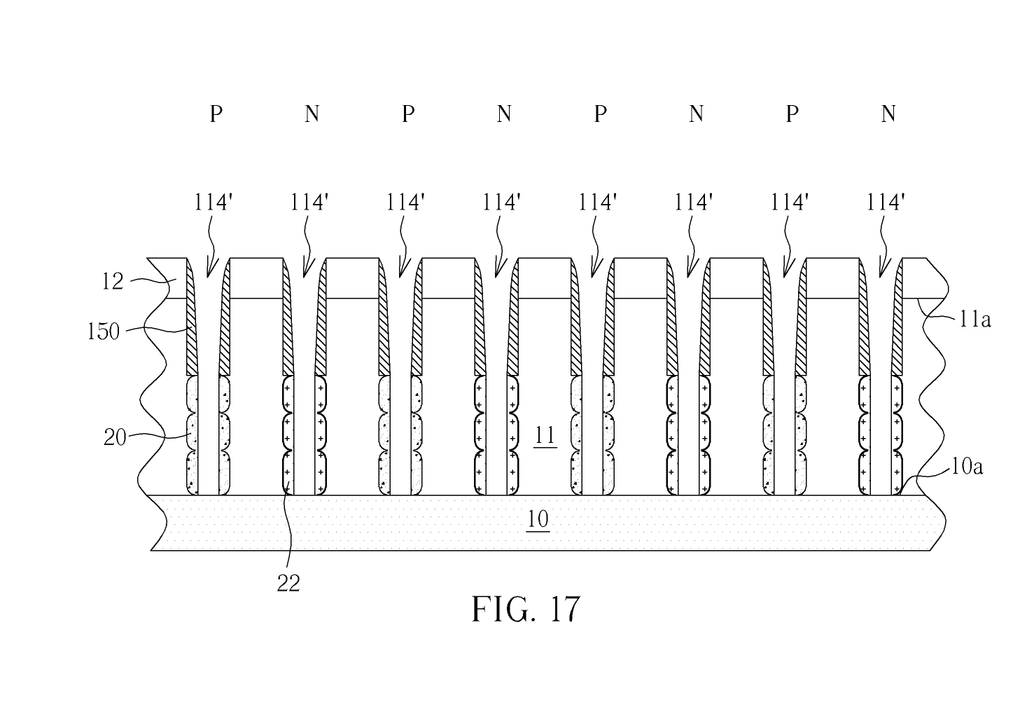

As shown in FIG. 17, after forming the P type doping regions 20 and N type doping regions 22, a second anisotropic dry etching process is performed using the hard mask pattern 12 as an etching mask to continue to etch the semiconductor layer 11 through the plurality of first trenches 114, thereby forming a plurality of second trenches 114′ having a trench depth that substantially reaches the semiconductor substrate 10.

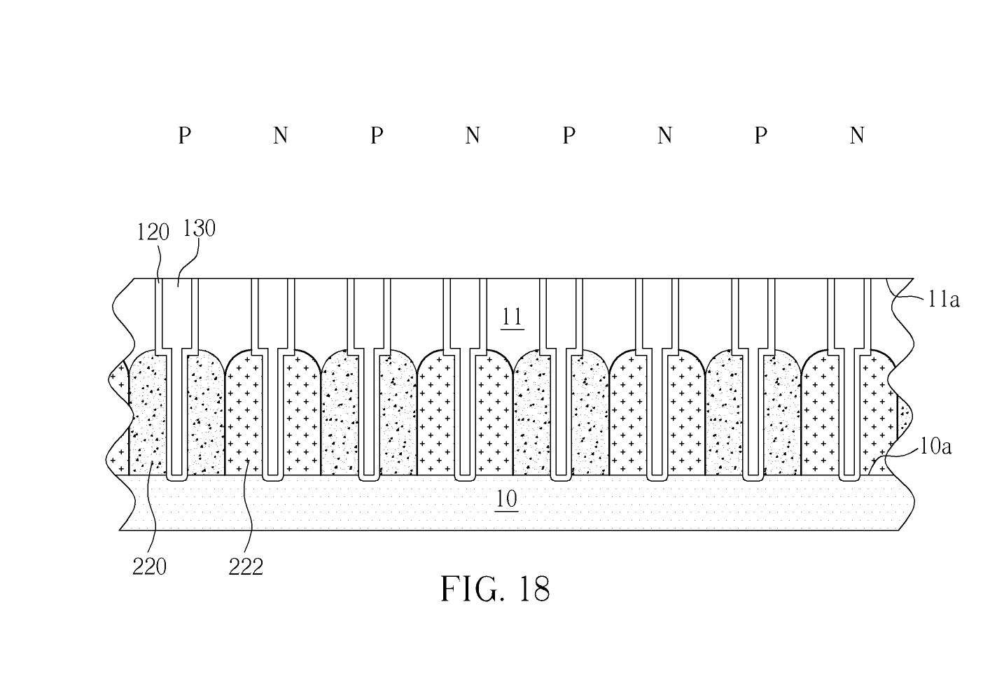

Subsequently, as shown in FIG. 18, after the formation of the second trenches 114′, the spacer 150 is removed. A liner layer 120 such as silicon oxide is then formed on the bottom surface and sidewall surface of the second trenches 114′. According to this embodiment, the liner layer 120 may be a dielectric layer and may be formed by using thermal oxidation methods, but not limited thereto. Subsequently, a CVD process is performed to deposit a trench fill dielectric 130 in a blanket manner. The trench fill dielectric 130 may be a silicon oxide layer and fills the second trenches 114′. The trench fill dielectric 130 also covers the hard mask pattern 12. A CMP process is then performed to remove a portion of the trench fill dielectric 130. Thereafter, the hard mask pattern 12 is removed. The subsequent processes are similar to the steps as depicted in FIGS. 8-13 and are therefore omitted.

To sum up, the present invention double-doping trench-type superjunction power semiconductor device is characterized in the P type doping trenches provided between the N type doping trenches. The P type doping trenches and the N type doping trenches are subjected to P type and N type ion implantation processes respectively to form the superjunction structure. As previously mentioned, the P type diffusion region 220 and the N type diffusion region 222 together present a symmetric gradient profile of doping concentration with respect to the PN junction 200 between the P type diffusion region 220 and the N type diffusion region 222. Further, the distance d1 between the PN junction 200 and centerline 230 of one adjacent second trench 114′ is substantially equal to the distance d2 between the PN junction 200 and centerline 230 of another adjacent second trench 114′.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power semiconductor device, comprising:
a substrate with a first conductivity type;
a semiconductor layer grown on the substrate, the semiconductor layer having a the first conductivity type;
a plurality of alternately arranged first conductivity type doping trenches and second conductivity type doping trenches in the semiconductor substrate;
a first diffusion region of the first conductivity type, in the semiconductor layer and around each of the first conductivity type doping trenches; and
a second diffusion region of the second conductivity type, in the semiconductor layer and around each of the second conductivity type doping trenches, wherein a distance between an edge of the first conductivity type doping trench and a PN junction between the first and second diffusion regions substantially equals to a distance between an edge of the second conductivity type doping trench and the PN junction.

2. The power semiconductor device according to claim 1 further comprising a trench gate situated within the first conductivity type doping trench.

3. The power semiconductor device according to claim 1 further comprising a source having the first conductivity type situated in the semiconductor layer and around each of the first conductivity type doping trenches.

4. The power semiconductor device according to claim 1 wherein the first conductivity type is N type and the second conductivity type is P type.

5. The power semiconductor device according to claim 1 wherein the substrate is an N⁺ silicon substrate.

6. The power semiconductor device according to claim 1 wherein the semiconductor layer is an N type epitaxial silicon layer.

7. The power semiconductor device according to claim 1 wherein the semiconductor layer is a lightly doped epitaxial layer having a doping concentration less than 1E14 atoms/cm3.

8. The power semiconductor device according to claim 1 further comprising a dopant concentration gradient that is substantially symmetric about a junction between the first diffusion region of the first conductivity type and the second diffusion region of the second conductivity type.
